(19) United States
(12) Patent Application Publication
(10) Pub. No.: US 2004/0003340 A1
(43) Pub. Date: Jan. 1, 2004

(54) Modulo arithmetic overflow control for viterbi decoder

(75) Inventors: Michael Chen, Irvine, CA (US); Mike Tomlinson, Aliso Viejo, CA (US)

Correspondence Address: Philip K. Yu, Registered Patent Attorney, Ste. 160, 20955 Pathfinder Road, Diamond Bar, CA, 91765, US

(73) Assignee: 3DSP Corporation

(21) Appl. No.: 10/183,648

(22) Filed: Jun. 26, 2002

(51) Int. Cl. H03M 13/03

(52) U.S. Cl. 714/795

(57) ABSTRACT

A method and apparatus for controlling overflow in Viterbi decoder is disclosed. The present invention allows the metrics to use short words, and to grow freely, by the use of natural wrap-back when overflow occurs. The metric compare process monitors the occurrence of wrap-back and produces results accordingly. In accordance with one aspect of the invention, a “partial subtractions” is used for the compare processes by checking the most-significant bit of each “partial subtraction” result, instead of the carry bit, to determine the comparison result. Based on the comparison result, the metric will be selected, or updated, at the next stage.

### FIELD OF THE INVENTION

The present invention relates to digital signal processing for wireless and wired communication channels, and more particularly relates to digital signal processing using Viterbi decoders for error correction purposes.

### ART BACKGROUND

It has been quite common to use Viterbi decoders in digital signal processing for wireless and wired communication channels. Because of errors and corrupt data which invariably occur in the channels, Viterbi decoders have been used at the receiver end to correct error caused by noise and interference. Viterbi decoder decodes data that have been encoded when transmitted from the transmitter end. Data at the receiver end are then applied to a decoder, such as the Viterbi decoder, to correct errors. FIG. 1 illustrates a typical transmitter and receiver setup in a communication channel. After decoder processing, as well as well as filtering and other signal processing, original data can be reproduced.

At the receiver side, the Viterbi decoder processing typically takes up more than 50% of the digital base-band design, while the rest comprises fast Fourier transform, equalization, filtering and mapping. The Viterbi decoder processing is typically the largest in terms of cycle counts. Therefore, how efficient the Viterbi decoder operates will have a significant impact on the overall receiver processing.

Typically, one of the most consuming parts of a typical Viterbi decoder processing is the routines of Add, Compare and Select computations, which are recursively performed to compute and update, or select, the metrics in a Viterbi trellis. In order to select the metric of a node at the next stage, the metric at the node in a previous stage is first added with its branch metric to arrive at a value. The metric at another state in the same stage is also added with its branch metric to arrive at a value. Both values are compared to determine the maximum value among the two, which is then selected for the node at the next stage. Such Add, Compare and Select routines must occur throughout all the nodes in each stage. As computation continues, the metrics will grow and will eventually become overflow. As can be appreciated by those skilled in the art, overflow may occur either because the word length used for the metric is insufficient, or the processing becomes too protracted.

Conventionally, overflow in Viterbi decoder processing is prevented by either using longer words in the metric computation, or subtracting a common value from all the metrics, before the metrics become too large. However, such measures have become more and more undesirable, since as the states grow, e.g. 64 states, it will be necessary to subtract for all 64 nodes, which takes up precious cycle time, especially when the whole cycle time for a 64-state stage may only take a few cycles for a programmable DSP, or one cycle for an ASIC design.

Additionally, such overflow prevention measures seem to place undue emphasis on keeping track of the values of the metrics while preventing overflow, whereas it is the “result” of the comparison between the metrics that is needed for the decoder's trace-back.

Instead of subtracting at every stage, some conventional technique only subtracts after the processing has progressed for a while. Such technique is not entirely appealing, since the frequency of subtracting is still largely dictated by the metric's word size. Longer words in metric computation can prevent overflow; however, the trade-off now is that the resulting computations are done with longer words.

Other conventional approaches to control overflow include: subtracting a minimum metric at each stage for all the states, or subtracting the metrics at each stage by any one of metrics, or just a common value, without having to find a minimum for the stage. Neither of the conventional techniques seems attractive since they both require measures to prevent overflow, at the price of excessive cycle time, or increased word length for the metrics.

Therefore, it is desirable to be able to perform the Add, Compare and Select routines for a Viterbi decoder in a cycle-efficient manner.

It is also desirable to be able to control overflow for a Viterbi decoder without incurring complicated computations such as finding a minimum for subtraction or subtracting by a common value.

### SUMMARY OF THE INVENTION

A method and apparatus for controlling overflow in Viterbi decoder is disclosed. The present invention allows the metrics to use short words, and to grow freely, by the use of natural wrap-back when overflow occurs. The metric compare process monitors the occurrence of wrap-back and produces results accordingly. In accordance with one aspect of the invention, a “partial subtractions” is used for the compare processes by checking the most-significant bit of each “partial subtraction” result, instead of the carry bit, to determine the comparison result. Based on the comparison result, the metric will be selected, or updated, at the next stage.

### BRIEF DESCRIPTION OF THE DRAWINGS

FIG. 1 illustrates a typical transmitter and receiver setup in a communication channel.

FIG. 2 is a simplified exemplary 4-state trellis diagram shown to illustrate the Add, Compare and Select routine in Viterbi decoding.

FIG. 3(a) is simplified diagram illustrating an exemplary word size and the distribution of metric values.

FIG. 3(b) is a simplified diagram illustrating the wrap-around.

FIG. 3(c) is a simplified diagram illustrating the intervals of metrics for a modified compare.

FIG. 4 is a simplified diagram of an exemplary embodiment of overflow control in accordance with the one embodiment of the present invention.

FIG. 5 is a representation of an exemplary ASIC field of the Compare instruction for the Viterbi decoder in accordance with one embodiment of the present invention.

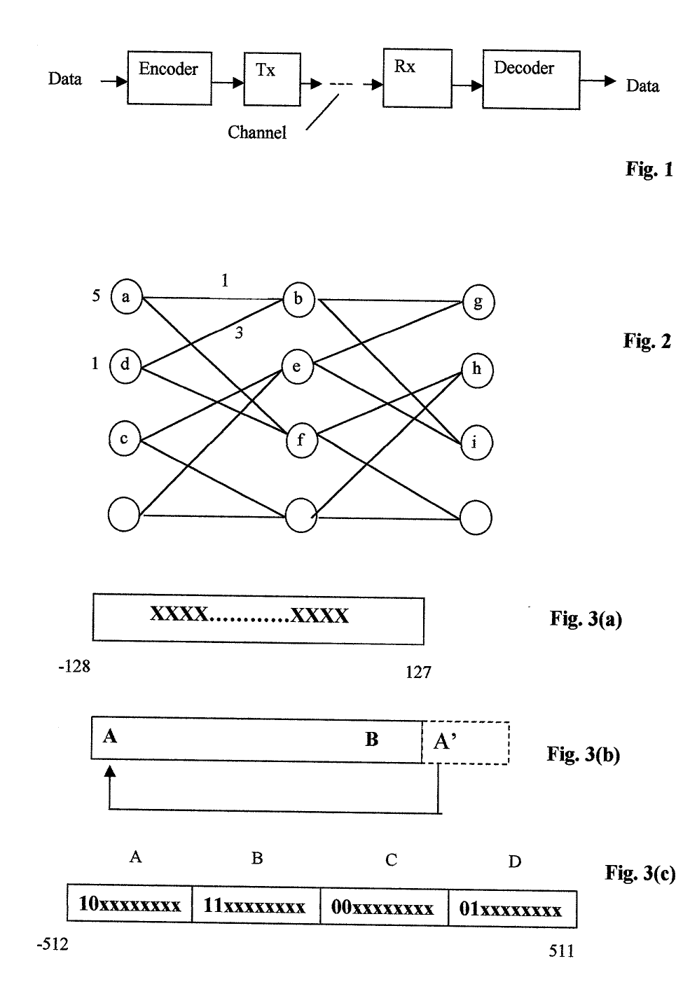

### DETAILED DESCRIPTION OF THE PREFERRED EMBODIMENTS

A method and apparatus for controlling overflow in Viterbi decoding of data encoded by convolutional coding in a communications channel is disclosed. In the following detailed description, numerous specific details are set forth to provide a full understanding of the present invention. It will be obvious, however, to one ordinarily skilled in the art that the present invention may be practiced without some of these specific details. In other instances, well-known structures and techniques, e.g. trellis computation, binary subtraction or binary comparison techniques, have not been shown in detail so as to avoid unnecessarily obscuring the present invention.

Reference is to FIG. 2, where a simplified trellis diagram is shown to illustrate the Add, Compare and Select routine in Viterbi decoding. As shown in FIG. 2, assume node a has a state metric value of 5, node d has a state metric value of 1, branch a-b has a metric value of 1 and branch d-b has a metric value of 3. To determine the state metric value of node b, the routine of Add, Compare and Select is performed as follows: Metric of node a is added to metric of branch a-b to get a path metric of 5+1=6. Also, metric of node c is added to metric of branch c-b to get a path metric of 1+3=4. Both path metrics from paths a-b and c-b are compared to determine the maximum value, which is the path metric of 6 from path a-b. Now, the state metric of node b is updated or selected as 6. Such routine is repeated for all the nodes throughout the trellis.

As previously mentioned, the state metrics for all the nodes in the trellis can easily become quite complex, after iterations of computation, thus risking overflow during the addition and comparison steps. As can be appreciated by those skilled in the art, a comparison between two values is typically carried out as subtraction or by dedicated compare logic circuit between the two values for binary computations.

To control overflow, in accordance with one embodiment of the present invention, a maximum difference between any two nodes is used such that a proper word size to represent the metric can be designed. It should be appreciated by those skilled in the art that the maximum difference between any two nodes of the trellis can readily be obtained by calculation of any given system.

For example, it is well known to those skilled in the art of GSM communication systems that the maximum difference between any two nodes in a GSM trellis is 116, assuming a 4-bit soft-decision decoder is used. This maximum difference can comfortably be accommodated by an 8-bit word, since 2⁸=256 and 256>2×116. In a normal situation without overflow, all the data points for the nodes might be distributed within the ranges of an 8-bit word spectrum, as graphically (represented as “x” marks) illustrated in FIG. 3(a).

However, if overflow does occur and is allowed to occur, the values can be represented, in accordance with one embodiment of the present invention, by wrapping back to the other end of the 8-bit word spectrum, as illustrated by metric A in FIG. 3(b). By allowing overflow and wrapping back, the need to subtract a common or a minimum value in order to prevent overflow, as is the case with conventional approaches, is obviated.

After the two corresponding state metrics are added with their corresponding branch metrics, two corresponding path metrics are obtained. Thereafter, the two path metrics will be Compared. When two state metrics, such as metrics A and B of FIG. 3(b), are to be Compared, B is subtracted by A. Alternatively, a modified comparison (to be described in connection with FIG. 3(c)) between A and B may also be used to compare the two metrics. However, instead of keeping track of the result of subtraction, only the most-significant bit (“MSB”) is obtained, since the MSB now indicates which of A or B is larger. For the sake of convenience, this subtraction is called “partial-subtraction.” For example, if A is a negative number because of the overflow and wrap-back and B is a positive number, then the Comparison will take the following form:

B−A=0xxxxxxx−1xxxxxxx=11xxxxxxx, where “x” can be either a “0” or “1”.

Looking at the MSB (not the carry), if the MSB is a “1”, it indicates that metric A is larger since it must have been wrapping back from a larger, positive value than metric B (shown as A′ in FIG. 3(b)). If the MSB is a “0”, it indicates that B is larger. Once the Comparison is carried out with the resultant MSB obtained, it becomes immaterial as to what the rest of the result is, since the MSB of the difference of subtraction now gives the telltale sign. Whichever metric is larger based on the Comparison, then that metric will be Selected/Updated at the next node.

Reference is to FIG. 3(c), where a simplified diagram of a range of metrics in connection with the Modified Compare is illustrated. The numbers covered by vectors of 10 (for example, one can use 9, 11, or any other numbers) bits are from −512 to 511 and may be divided into four intervals, A, B, C and D. The metric value in each interval will take the form of 10xxxxxxxx, 11xxxxxxxx, 00xxxxxxxx, 01xxxxxxxx, for intervals A, B, C, and D, respectively. As can be understood, all the metric values in each interval will have the same most significant 2 bits in the case of 4 intervals. Of course, if 8 intervals are used, then all the metrics in the same interval will have the most significant 3 bits the same.

When two metrics are compared, it is only necessary to compare the first, or the most significant, 2 bits (for the case of 4 intervals). For example, to compare a metric from interval A and interval B, “10” will be compared with “11” and “11”>“10”, using the partial subtraction described above. In this case, the compare between two metrics is completed.

However, if two metrics from the same interval are compared, then the first 2 bits will be the same. Then it would be necessary to do a conventional unsigned compare of the rest of the bits to determine which one is larger. For some designs, both comparisons, i.e. the signed and unsigned, may take place concurrently, so that the results may be readily available.

Note that the numbers from interval D are smaller than the numbers from interval A. This result stems from the rules of the aforementioned partial subtraction, if the first 2 bits are used in that subtraction.

The first 2 bits can thus be called the MSB section, while the other 8 bits are called the LSB section.

With the modified compare, wrapping around will be taken care of. However, the allowed metric range span of the metric values (the largest distance of the numbers for the state metrics) is 256, instead of 511, i.e. Largest−Smallest=256.

To enlarge the allowed metric range span, the range of all the 10 bit numbers may be divided into 8 or even 16 intervals or more. As such, the MSB section will be longer while the LSB section is shortened.

Therefore, for any two numbers, their MSB sections are first compared, using the aforementioned partial subtraction. If they are different, the result is used as the final result of the compare. If the MSB sections are the same, then a conventional unsigned comparison of the LSB sections is used to determine which one is larger. As such, the comparison can be done faster, since each section is shorter than the whole number, e.g. 2 bits/8 bits vs. 10 bits. While the range allowed in this case is smaller, one can divide the whole range into more intervals by using more bits in the MSB section, and the reduction of the range will be small.

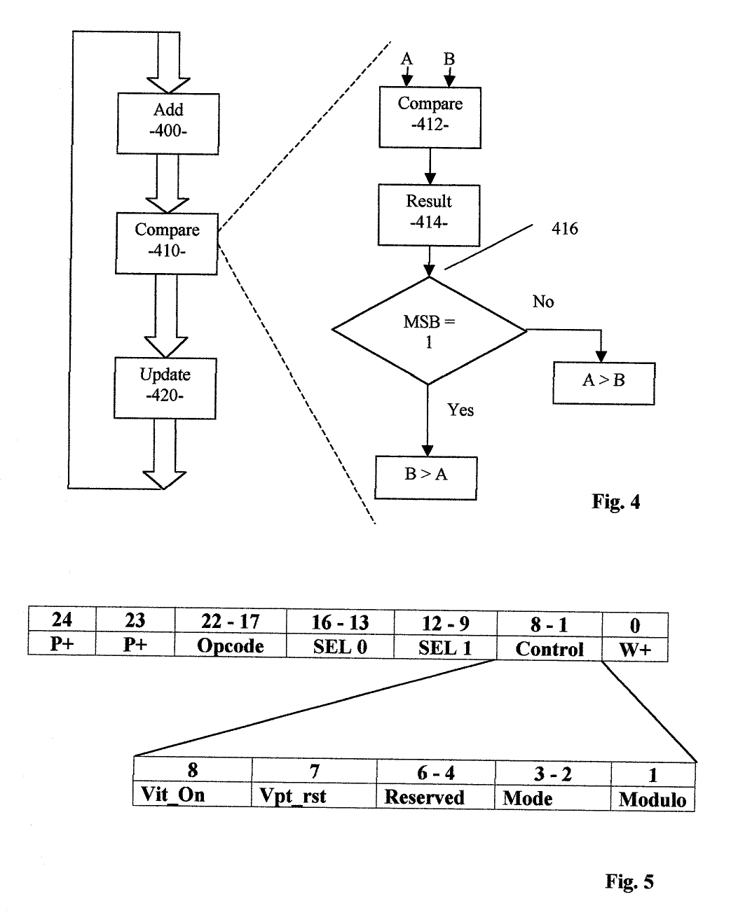

Reference is to FIG. 4, where a simplified diagram of one exemplary overflow control in accordance with one embodiment of the present invention is shown. At each node, the branch metrics are Added 400. They are then Compared (410), which subtracts “A” from “B” (412). While result 414 encompasses just as many bits as the metrics themselves, only the MSB is looked at to determine the relative value between “A” and “B.” Once it is determined, the larger value of either “A” or “B” is Selected/Updated (420).

As can now be appreciated by those skilled in the art, the modulo arithmetic overflow control for Viterbi decoders in accordance with the present invention allows the metrics to use short words and to grow freely, with wrapping back naturally when overflow occurs and obviates the need to do any computations to adjust the metrics in the Viterbi decoding process. For some programmable DSP applications, e.g. where the state metrics can be either 8-bit or 16-bit and 8-bit is chosen, the methodology in accordance with the present invention has illustrated an increase of the speed of Viterbi decoding by 100% without altering its complexity.

The following illustrates an exemplary new COMPARE instruction for a Viterbi decoder in a programmable DSP in accordance with one embodiment of the present invention. It should be pointed out that those skilled in the art may readily design their instructions and systems based on the following example: Format:

1P+IP-(U+J destR =MAXK8161(srcA, srcB [,reset])

We use a 5-bit field (as a 5-bit binary number) from a control register as a pointer. Let's call it Vpt. A 32-bit register named Viterbi is used to store the indices resulting from the comparison.

Vpt is incremented by 1, 2 or 4 after the compare operation according to whether 32 bit, 16 bit or 8 bit option is taken. Vpt is modular 32, and overflow means wrapping back and starting from 0.

Vpt is set to 0 before the compare operation if “reset” option is used. The post increment will still be executed.

The destR will get srcA or srcB according the result of the partial subtraction.

For 32-bit compare, the resulting indices of the comparison will be put in register Viterbi as follows (Note that partial subtraction should be applied in the comparison):

If srcA>=srcB then viterbi[Vpt:Vpt]=0

If srcA<srcB then viterbi[Vpt:Vpt]=1

For 16-bit compare, the resulting indices of the comparison will be put in register Viterbi as follows (Note that modulo arithmetic should be applied in the final design):

If srca.h>=srcB.h then viterbi[Vpt+1:Vpt+1]=0

If srcA.h<srcB.h then viterbi[Vpt+1:Vpt+1]=0

If srcA.l>=srcB.l then viterbi[Vpt:Vpt]=0

If srcA.l<srcB.l then viterbi[Vpt:Vpt]=1

For 8-bit compare, the resulting indices of the comparison will be put in register Viterbi as follows (Note that modulo arithmetic should be applied in the final design):

If srcA[31:24]>=srcB[31:24] then viterbi[Vpt+3:Vpt+3]=0

If srcA[31:24]<srcB[31:24] then viterbi[Vpt+3:Vpt+3]=1

If srcA[23:16]>=srcB[23:16] then viterbi[Vpt+2:Vpt+2]=0

If srcA[23:16]<srcB[23:16] then viterbi[Vpt+2:Vpt+2]=1

If srcA[15:8]>=srcB[15:8] then viterbi[Vpt+1:Vpt+1]=0

If srcA[15:8]<srcB[15:8] then viterbi[Vpt+1:Vpt+1]=1

If srcA[7:0]>=srcB[7:0] then viterbi[Vpt:Vpt]=0

If srcA[7:0]<srcB[7:0] then viterbi[Vpt:Vpt]=1

The ASIC field is shown in FIG. 5, where Opcode is the partial subtraction MAX/MIN opcode.

The 5-bit field [20:16] in the CR_ASIC0 register (where the Cmp_flag field stays in) is used as the Vpt pointer.

Vit_On: Viterbi mode enable:

‘0’=normal ASIC instruction

‘1’=Viterbi instruction.

Bits 7˜1 shown above are all for the Viterbi mode.

Vpt_rst: ‘1’=reset Vpt to zero.

Modulo: Modulo arithmetic

‘1’=The modulo arithmetic is used in the comparison.

Mode: Determines 32, 16, or 8-bit mode as usual.

Vpt is post incremented by

1 if Mode=‘00’

2 if Mode=‘01’

4 if Mode=‘11’

The post incremented is executed even if Vpt_rst=1.

The present invention may be embodied in other specific forms without departing from the spirit or essential characteristics thereof. The present embodiments are to be considered in all respects as illustrative, and not restrictive. The scope of the invention is therefore, indicated by the appended claims rather than by the foregoing description, and all changes which come within the meaning and range of equivalency of the claims are to be embraced within their scope.

We claim:

1. In a communications channel, where data are encoded and transmitted across the communication channel for reception and decoding using a multi-state trellis Viterbi decoder, a method of conducting ADD, Compare and Select routine in said Viterbi decoder, comprising:
a. designating a range, said range being adapted to represent the maximum of differences between any two nodes of said trellis;
b. for a node at each stage, adding a first branch metric to a first state metric and generating a first metric;
c. if said first metric overflows said range, representing said first metric in another value within said range according to a predetermined criteria;
d. for said node at said stage, adding a second branch metric to a second state metric and generating a second metric;
e. if said second metric overflows said range, representing said second metric in another value within said range according to a predetermined criteria;
f. comparing said second metric with said first metric and generating a result having an MSB section and an LSB section;
g. if said MSB section is a first predetermined value, then updating a node at the next stage with said second metric, and if said MSB section is a second predetermined value, then updating said node at the next stage with said first metric,
h. repeating steps b)-g) for each node and for each stage.

2. The method of claim 1, wherein the step of comparing comprises subtracting said first metric from said second metric.

3. The method of claim 1, wherein said predetermined criteria comprises a step of wrapping around said metric within said range.

4. The method of claim 2, wherein said predetermined criteria comprises a step of wrapping around said metric within said range.

5. The method of claim 3, wherein said first predetermined value is 1 and said second predetermined value is 0.

6. The method of claim 4, wherein said first predetermined value is 1 and said second predetermined value is 0.

7. In a communications channel between a transmitter and a receiver, said transmitter being adapted to encode and transmit data, said receiver being adapted to receive and decode data, a method of conducting ADD, COMPARE and SELECT routine in a Viterbi decoder with a multi-state trellis having a plurality of stages of nodes, each node having a state metric selected from one of two path metrics from a previous stage, each node having two branches leading to a next stage, said method comprising the steps of:
a. adding a first state metric to a first branch metric of a first branch, and generating a first path metric, said first branch leading to a node in a next stage;
b. translating said first path metric, if it overflows;
c. adding a second state metric to a second branch metric of a second branch, and generating a second path metric, said second branch leading to said node in said next stage;
d. translating said second path metric, if it overflows;
e. comparing said first and second path metrics, and generating a comparison result having an MSB section and an LSB section;
f. using said MSB section to determine which one of said first and second path metrics is larger, in accordance with a predetermined criteria;
g. updating said node in said next stage based on the larger of said first and second path metrics;
h. repeating steps a)-g) for each node at each stage of the trellis.

8. The method of claim 7, wherein said steps of translating said path metrics comprise wrapping around said metrics within a predetermined range in case of overflow.

9. The method of claim 7, wherein said step of comparing comprises subtracting said first path metrics from said second path metrics.

10. A method of decoding received signals using a Viterbi decoder in a communications channel, said Viterbi decoder having a multi-state trellis, the method comprising:
a. at a node for each stage, adding first and second state metrics to first and second branch metrics to obtain first and second path metrics, respectively, for a node;
b. at said node for said stage, comparing said first and second path metrics to obtain a result having at least one most significant bit (“MSB”);
c. determining which one of said first and second path metrics is larger based on said at least one MSB;
d. selecting one of said first and path branch metrics that is larger as a state metric of said node.

11. The method of claim 10, wherein said step of comparing comprises subtracting said first path metric by said second path metric.

12. The method of claim 10, wherein said steps (a) through (d) are repeated for each node in every state of every stage of said trellis.

13. The method of claim 11, wherein said steps (a) through (d) are repeated for each node in every state of every stage of said trellis.

14. The method of claim 10, further comprising a step of determining a maximum range for all metrics in said trellis.

15. The method of claim 1, wherein both of said first metric and said second metric have an MSB section and an LSB section, said step of comparing comprises:
comparing said MSB sections of said first and second metrics;
comparing said LSB sections, if said MSB sections are the same, using unsigned comparison.

16. The method of claim 7, wherein both of said first metric and said second metric have an MSB section and an LSB section, said step of comparing comprises:
comparing said MSB sections of said first and second metrics;
comparing said LSB sections, if said MSB sections are the same, using unsigned comparison.

17. The method of claim 16, wherein said MSB section has 2 bits and said LSB section has 8 bits.
